(19) United States
(12) Patent Application Publication
(10) Pub. No.: US 2009/0189628 A1
(43) Pub. Date: Jul. 30, 2009

(54) Reworkable bonding pad layout and debug method thereof

(76) Inventors: Chih-Chien Lee, Taipei City (TW); Wei-Fan Ting, Taipei City (TW); Ting-Chang Lin, Taipei City (TW)

Correspondence Address: Chih Feng Yeh;BRIAN M. MCINNIS, 12th Floor, Ruttonjee House, 11 Duddell Street, Hong Kong, HK

(21) Appl. No.: 12/010,453

(22) Filed: Jan. 25, 2008

(51) Int. Cl. G01R 31/02; H05K 1/16

(52) U.S. Cl. 324/763; 174/260

(57) ABSTRACT

The reworkable bonding pad layout includes a first point, a second point, a reworkable bonding pad, a first leading wire, and a second leading wire. There is a debug position defined between the first point and the second point. The reworkable bonding pad is formed at the debug position. The first leading wire may connect the reworkable bonding pad and the first point. The second leading wire may connect the reworkable bonding pad and the second point. The reworkable bonding pad is cut into a first debug area connecting with the first leading wire, and a second debug area connecting with the second leading wire.

### BACKGROUND

1. Field of Invention

The present invention relates to a bonding pad layout. More particularly, the present invention relates to a reworkable bonding pad layout.

2. Description of Related Art

A debug process is usually applied after an IC device is mounted on a printed circuit board (PCB) to ensure the printed circuit board and the IC chips operate normally. The debug process is usually applied after the layout process. The components for the debug process are built on the printed circuit board during the layout process. There is a 0 ohm resistor at the debug position of the printed circuit board to prevent a short circuit and maintain the rework flexibility during the debug process. The 0 ohm resistor can be removed during the debug process, and the debug engineer can debug the components leading to the debug position respectively. The material and the cost for building the 0 ohm resistor needs to be considered.

### SUMMARY

The invention provides a reworkable bonding pad layout for debugging a printed circuit board. The reworkable bonding pad layout includes a first point, a second point, a reworkable bonding pad, a first leading wire, and a second leading wire. There is a debug position defined between the first point and the second point. The reworkable bonding pad is formed at the debug position. The first leading wire may connect the reworkable bonding pad and the first point. The second leading wire may connect the reworkable bonding pad and the second point. The reworkable bonding pad is cut into a first debug area connecting with the first leading wire, and a second debug area connecting with the second leading wire.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram of an embodiment of the reworkable bonding pad layout of the invention; and

FIG. 2 is a schematic diagram of different states of the embodiment of the reworkable bonding pad of the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

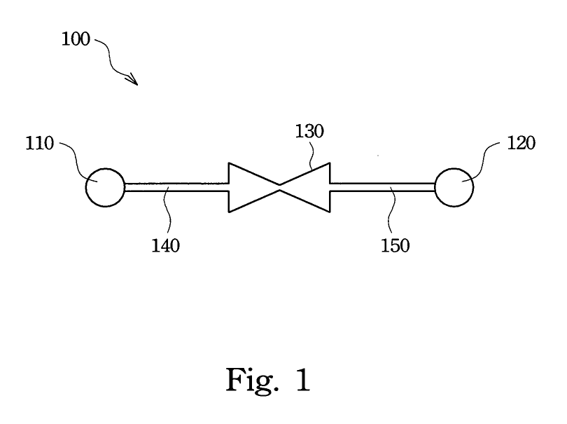

Refer to FIG. 1. FIG. 1 illustrates a schematic diagram of an embodiment of the reworkable bonding pad layout of the invention. The reworkable bonding pad layout 100 may be applied to debug a printed circuit board. The reworkable bonding pad layout 100 could replace a conventional 0 ohm resistor during the debug process. The reworkable bonding pad layout 100 includes a first point 110, a second point 120, and a reworkable bonding pad 130. A debug position is defined between the first point 110 and the second point 120 when a layout engineer designs the printed circuit board. The reworkable bonding pad 130 is formed at the debug position. The reworkable bonding pad layout 100 includes a first leading wire 140 to connect the reworkable bonding pad 130 and the first point 110. The reworkable bonding pad layout 100 includes a second leading wire 150 to connect the reworkable bonding pad 130 and the second point 120.

The reworkable bonding pad 130, the first leading wire 140, and the second leading wire 150 may be regarded as a continuous and complete part. The first leading wire 140, the second leading wire 150, and the reworkable bonding pad 130 may be regarded as a single point, not a short circuit.

The material of the reworkable bonding pad 130 may be copper. The shape of the reworkable bonding pad 130 may be a hourglass shape. The first point 110 and the second point 120 may a footprint connecting with a pin of an integrate circuit chip. The first point 110 and the second point 120 may be a via of the printed circuit board. For example, the first point 110 and the second point 120 may be a grounded via.

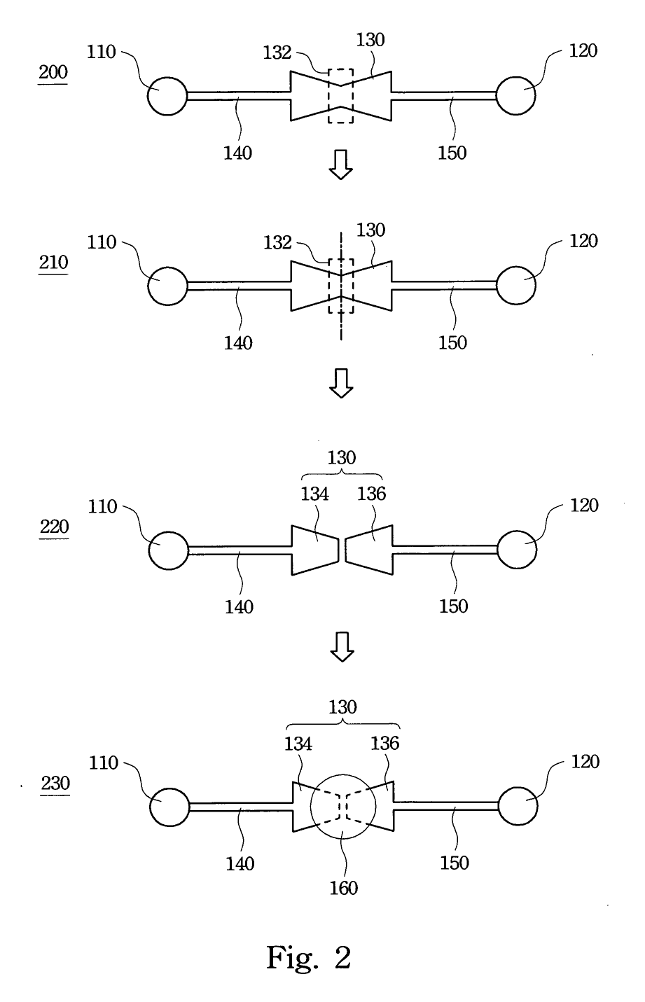

Refer to FIG. 2. FIG. 2 illustrates a schematic diagram of different states of the embodiment of the reworkable bonding pad of the invention. The reworkable bonding pad 130 is formed on the printed circuit board in state 200. The reworkable bonding pad 130 is leading to the first point 110 and the second point 120 with the first leading wire 140 and the second leading wire respectively. The reworkable bonding pad 130 has a middle area 132. The width of the middle area 132 is narrower than two opposite sides of the reworkable bonding pad 130. The middle area 132 of the reworkable bonding pad 130 is cut along the middle area 132 at state 210. The reworkable bonding pad 130 has been cut as shown in state 220. The reworkable bonding pad 130 is cut into a first debug area 134 and a second debug area 136. The first debug area 134 is connected with the first leading wire 140, which is leading to the first point 110. The second debug area 136 is connected with the second debug area 136, which is leading to the second point 120. A debug engineer may debug with the first debug area 134 and the second debug area 136. In state 230, a solder 160 may be soldered on the reworkable bonding pad 130 to connect the first debug area 134 and the second debug area 136 to connect the first point 110 and the second point 120 after finishing the debug process.

The first point 110 and the second point 120 may be connected with the reworkable bonding pad 130 and be regarded as a complete part. Thus, the unusual short circuit between the first point 110 and the second point 120 cannot be detected. The reworkable bonding pad 130 can be cut into the first debug area 134 and the second debug area 136. The reworkable bonding pad 130 can replace the conventional 0 ohm resistor during the debug process. The debug engineer can debug the printed circuit board with first debug area 134 and the second debug area 136 respectively. The solder 160 can be soldered on the reworkable bonding pad 130 to connect the first debug area 134 and the second debug area 136 after the debug process.

The reworkable bonding pad may be formed on the printed circuit board with normal bonding pads. The reworkable bonding pad may replace the conventional 0 ohm resistor during the debug process. The material and the process for preparing the 0 ohm resistor can be omitted.

Furthermore, the conventional leading wires are coated with a passive material, and the solder cannot be soldered on the leading wire. The leading wire cannot be soldered after the leading wire is cut. The reworkable bonding pad in this invention can be cut and soldered. The reworkable bonding pad in this invention has a special shape, such as the hourglass, and the debug engineer may easily recognize the reworkable bonding pad between the first point and the second point.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A reworkable bonding pad layout for debugging a printed circuit board, the reworkable bonding pad layout comprising:
a first point;
a second point, wherein a debug position is defined between the first point and the second point;
a reworkable bonding pad formed at the debug position;
a first leading wire connecting the reworkable bonding pad and the first point; and
a second leading wire connecting the reworkable bonding pad and the second point,
wherein the reworkable bonding pad is cut into a first debug area connecting with the first leading wire, and a second debug area connecting with the second leading wire.

2. The reworkable bonding pad layout of claim 1, wherein a shape of the reworkable bonding pad is an hourglass shape.

3. The reworkable bonding pad layout of claim 1, wherein the reworkable bonding pad comprises a middle area and two opposite sides, and a width of the middle area is narrower than the opposite sides.

4. The reworkable bonding pad layout of claim 1, wherein the first point is a via of the printed circuit board.

5. The reworkable bonding pad layout of claim 1, wherein the first point is a footprint connecting with a pin of an integrate circuit chip.

6. The reworkable bonding pad layout of claim 1, wherein the second point is a via of the printed circuit board.

7. The reworkable bonding pad layout of claim 1, wherein the second point is a footprint connecting with a pin of an integrate circuit chip.

8. The reworkable bonding pad layout of claim 1, further comprising a solder soldered on the reworkable bonding pad for connecting the first debug area and the second debug area.

9. A debug method with a reworkable bonding pad comprising:
forming the reworkable bonding pad on a printed circuit board, wherein the reworkable bonding pad connects to a first point and a second point respectively;
cutting the reworkable bonding pad into a first debug area leading to the first point, and a second debug area leading to the second point; and
debugging the printed circuit board with the first debug area and the second debug area respectively.

10. The debug method with a reworkable bonding pad of claim 9, further comprising soldering a solder on the reworkable bong pad after debugging the printed circuit board to connecting the first debug area and the second debug area.

11. The debug method with a reworkable bonding pad of claim 9, wherein the reworkable bonding pad comprises a middle area and two opposite sides, and a width of the middle area is narrower than the opposite sides.

12. The debug method with a reworkable bonding pad of claim 11, wherein the reworkable bonding pad is cut along the middle area.

13. The debug method with a reworkable bonding pad of claim 11, wherein a shape of the reworkable bonding pad is an hourglass shape.

14. The debug method with a reworkable bonding pad of claim 11, wherein the first point is a via of the printed circuit board.

15. The debug method with a reworkable bonding pad of claim 11, wherein the first point is a footprint connecting with a pin of an integrate circuit chip.

16. The debug method with a reworkable bonding pad of claim 11, wherein the second point is a via of the printed circuit board.

17. The debug method with a reworkable bonding pad of claim 11, wherein the second point is a footprint connecting with a pin of an integrate circuit chip.
